(19) United States
(12) Patent Application Publication
(10) Pub. No.: US 2009/0211514 A1
(43) Pub. Date: Aug. 27, 2009

(54) Single crystal conversion process

(75) Inventors: Shen J. Dillon, Pittsburgh, PA (US); Martin P. Harmer, Trexlertown, PA (US)

Correspondence Address: DUANE MORRIS LLP - Allentown, 968 POSTAL ROAD, SUITE 110, ALLENTOWN, PA, 18109-9390, US

(73) Assignee: Lehigh University

(21) Appl. No.: 12/072,355

(22) Filed: Feb. 26, 2008

(51) Int. Cl. C30B 1/02

(52) U.S. Cl. 117/7

(57) ABSTRACT

A solid state method for converting polycrystalline alumina components to single crystal or sapphire. The single crystal conversion method includes sintering a pre-fired polycrystalline alumina component doped with a magnesia sintering aid in an atmosphere containing a gas mixture of hydrogen and an inert gas, such as nitrogen in one embodiment. A sintering temperature is selected that preferably depends on the percentage of hydrogen selected. The component is held at the sintering temperature for a time sufficient to convert the polycrystalline component into a component formed of a single crystal. In one embodiment, the sintering temperature may be between at least about 1600° C. and less than 2050° C., and the amount of hydrogen in the sintering atmosphere may be between about 4% to about 10%. The method forms a wetting type intergranular film associated with the nucleation and growth of a single abnormal grain in the polycrystalline alumina component.

### FIELD OF INVENTION

The present invention relates to a method for converting a polycrystalline alumina ceramic material into a single crystal (sapphire), and more particularly to controlling the sintering and conversion atmosphere.

### BACKGROUND OF THE INVENTION

Advanced ceramic materials made of alumina (i.e. aluminum oxide or Al₂O₃) have been used in numerous modern applications to make product component ranging from semiconductors to lighting such as translucent/transparent tubular plasma containment envelopes for high pressure sodium vapor arc discharge lamps. In one known solid state process for producing polycrystalline components having translucent/transparent properties such as for lighting applications, high purity alumina starter powders and sintering aids are first mixed and compacted into various-shaped solid bodies. These opaque porous ceramic bodies are then sintered entailing heating at relatively high temperatures below the melting point of the alumina (approximately 2050° C.) to form dense translucent/transparent components. Such a process is generally described in U.S. Pat. No. 3,026,210 to Coble, which is incorporated herein by reference in its entirety.

Polycrystalline alumina ceramic bodies, however, are less than ideal for plasma lamp envelopes and other applications requiring a relatively high degree of transparency. The polycrystalline bodies tend to be actually be more translucent than transparent. Sodium in the lamp arc may react with alumina at the grain boundaries forming sodium aluminate which adversely affects the structure integrity of the plasma envelope and shortens the service life of the lamp. Sodium and other plasma components may also diffuse through the grain boundaries of the plasma envelope into the evacuated outer lamp containment causing lamp discoloration and failures. In addition, the grain boundaries in polycrystals tend to scatter light and reduce the lamp's lighting efficiency.

To overcome the foregoing drawbacks of polycrystal for lighting applications or other applications, transparent single crystal or sapphire alumina bodies have been made from densified polycrystalline alumina. Processes for converting densified precursor polycrystalline bodies into single crystals are described in U.S. Pat. Nos. 5,451,553 and 5,683,949 to Scott et al. and U.S. Pat. No. 6,812,441 to Cheng et al., all of which are incorporated herein by reference in their entireties. Single crystal conversion is a process in which a single crystal is grown from a polycrystalline body by controlled abnormal grain growth. A densified precursor polycrystalline tube or other structure is essentially reheated to a relatively high temperature (>1000° C.) in a sintering atmosphere that may contain a vacuum, pure dry hydrogen, or inert gas. Ideally, a single abnormal grain is nucleated and progressively grows over time to eventually consume all other grains in the polycrystalline precursor, thereby forming a single crystal structure. The single crystal conversion process is generally shown in FIG. 1. However, known single crystal conversion processes generally require processing conditions that are very exacting in order to achieve any type of reproducible conversion, are time consuming since conversion rates are slow, and expensive making large-scale commercial production impractical for the most part.

Sintering aids such as magnesia (i.e. magnesium oxide or MgO) allows polycrystal alumina to reach full density necessary to become translucent/transparent. Finely divided alumina starter powder may be mixed with powdered magnesia or magnesium containing precursors before compacted “green” bodies are made and then sintered by heating at high temperatures to form the dense polycrystalline components. Typical densities required for translucent alumina are on the order of about at least 3.9 g/cc in some applications. However, magnesia doping has the undesirable side effect of preventing the formation of abnormal grain growth, which is at odds with the nucleation of a single abnormal grain necessary in the single crystal conversion process. In addition, magnesia doping can reduce grain boundary mobility which slows down the single crystal conversion process. Magnesia has been shown to reduce grain boundary mobility by three orders of magnitude. In some single crystal conversion processes, it is known to first separately heat the magnesia doped polycrystalline body in a vacuum, pure dry hydrogen, or inert gas to drive the magnesia out to a level that does not interfere with abnormal grain formation before the single crystal conversion process is begun, such as described in U.S. Pat. Nos. 5,683,949, 5,451,553, and 6,475,942, which are each incorporated herein by reference in their entireties. Starting concentrations of magnesia which may be about 300-600 ppm are preferably lowered to less than 50 ppm in these processes before initiating the conversion of the polycrystalline bodies into single crystal sapphires. However, this requires a separate and extra processing step which increases single crystal fabrication times and costs. In addition, known single crystal conversion processes for alumina are relatively slow and reproducible only about 30-40% of the time. Accordingly, known single crystal conversion techniques have not provided an effective commercially-viable solution to manufacture alumina-based single crystal products that is both practical and cost-effective for large-scale production.

An improved single crystal conversion process is therefore desirable.

### SUMMARY OF INVENTION

The present invention provides a method for solid state single crystal conversion of alumina ceramics that reduces the foregoing problems with known techniques, has greater reproducibility, and achieves faster conversion rates making the process better adapted for large scale commercial production. In one embodiment, the foregoing may be achieved in a single crystal conversion process by controlling the vaporization rate of magnesia dopant from polycrystalline bodies through control of the sintering atmosphere and sintering temperature. In a preferred embodiment, the sintering atmosphere includes a gas mixture consisting essentially of a partial pressure or concentration of hydrogen (H₂) and an inert gas. In one embodiment, a hydrogen-nitrogen mixture sintering atmosphere preferably is used in the single crystal conversion process. The single crystal conversion process is preferably conducted within a predetermined ideal sintering temperature range as further described herein that is selected based on the amount of hydrogen used in the sintering atmosphere. Exemplary process embodiments of the present invention also advantageously eliminate any extra steps of first separately heating the magnesia-doped polycrystalline alumina component or body to lower the residual magnesia content as in some known processes before single crystal conversion.

According to one embodiment, a solid state method for converting a polycrystalline alumina component into a single crystal component includes: providing a pre-fired polycrystalline alumina component having a residual amount of magnesia used as a sintering aid; heating the component to a predetermined temperature in a sintering atmosphere containing a gas mixture of nitrogen and a selected percentage of hydrogen, the temperature preferably being dependent on the percentage of hydrogen selected; and holding the component at said temperature for a time sufficient to convert the polycrystalline component into a single crystal component. Preferably, the magnesia is vaporized at a controlled rate sufficient to form a wetting-type intergranular film in the grain boundary between the single crystal and unconverted polycrystalline alumina in the component. This type of film is associated with the nucleation and growth of a single abnormal grain in the polycrystalline component which eventually consumes all other multiple grains. In another embodiment, the sintering temperature selected is preferably between at least about 1600° C. and less than 2050° C. and the amount of hydrogen in the sintering atmosphere is from about 4% to about 10%.

The optimized partial hydrogen pressure and sintering temperature process conditions described herein in the preferred embodiments promote the formation of a rich thick wetting-type intergranular film that is associated with high grain boundary mobilities and associated boundary/interface transport rates in alumina that are necessary for viable commercial production of single crystals. In some preferred embodiments, the wetting type intergranular film has a thickness of at least about 4 nm which is associated with true wetting behavior. More preferably, the intergranular film is at least about 10 nm thick, and in some embodiments the film thickness is preferably about 10 nm to about 20 nm which is associated with achieving reproducible commercial single crystal conversion in alumina ceramics. It will be appreciated by those skilled in the art that the foregoing film thicknesses may vary slightly between different individual grain boundaries. Film thickness greater than 20 nm are viable without adversely affecting the single crystal conversion process, and in some embodiments film thicknesses may up to 50 nm may be used. However, it is worth noting that grain boundary/interface transport rates or velocities are inversely proportional to intergranular film thickness. Therefore, thicker films will suppress grain boundary kinetics and increase conversion times. Accordingly, film thicknesses up to 20 nm are generally preferred with the single crystal conversion process described herein.

As the term is used herein, “grain boundary” refers to the boundary or interface between two grains in a polycrystalline material. With respect to the description herein of preferred embodiments of a single crystal conversion method for alumina, grain boundary will be used to describe the crystal-liquid-crystal interface between adjacent solid crystal structures (e.g. single crystal or polycrystals) with an intergranular wetting (“liquid”) film disposed therebetween.

### BRIEF DESCRIPTION OF THE DRAWINGS

The features of the preferred embodiments will be described with reference to the following drawings where like elements are labeled similarly, and in which:

FIG. 1 is a schematic diagram that graphically illustrates the single crystal conversion process including nucleation of a single abnormal grain and growth thereof;

FIG. 2 is a graph depicting the results of single abnormal grain growth in single crystal conversion tests conducted at a selected sintering temperature of 1945° C. for 4 hours and varying concentrations of hydrogen in a hydrogen-nitrogen sintering atmosphere;

FIG. 3A is an optical micrograph of a single abnormal grain growing through the thickness of a tube at an ideal combination of hydrogen content in the sintering atmosphere and sintering temperature;

FIG. 3B is an optical micrograph of multiple abnormal grains growing through the thickness of a tube at other than an ideal combination of hydrogen content in the sintering atmosphere and sintering temperature;

FIG. 4A is a photograph of polycrystalline alumina tube sample that was interrupted during the single crystal formation process and showing the interface between the growing single crystal and remaining polycrystals;

FIG. 4B is an optical micrograph of the single crystal-polycrystal grain boundary from the polycrystalline tube of FIG. 4A;

FIG. 4C is a diffuse dark-field TEM image of the single crystal-polycrystal grain boundary of FIG. 4B wherein a wetting-type intergranular film is visible;

FIG. 5 is a graph of ideal sintering temperatures versus percent hydrogen in a nitrogen sintering atmosphere from single crystal conversion tests;

FIG. 6A is an optical micrograph of a polycrystalline test sample sintered below the ideal conditions shown in FIG. 5 and showing multiple abnormal grains; and

FIG. 6B is an optical micrograph of a polycrystalline test sample sintered above the ideal conditions shown in FIG. 5 and showing multiple abnormal grains.

### DETAILED DESCRIPTION OF THE INVENTION

In the description of embodiments of the invention disclosed herein, any reference to direction or orientation is merely intended for convenience of description and is not intended in any way to limit the scope of the present invention. Moreover, the features and benefits of the invention are illustrated by reference to preferred embodiments. Accordingly, the invention expressly should not be limited to such preferred embodiments illustrating some possible but non-limiting combination of features that may be provided alone or in other combinations of features; the scope of the invention being defined by the claims appended hereto.

The inventors of the present invention have identified that a particular grain boundary phase or complexion in alumina having a true wetting-type intergranular film is associated with the nucleation and growth of a single abnormal grain in the single crystal conversion process. With magnesia-doped alumina polycrystalline precursor bodies, the inventors have further discovered that control of the vaporization rate of magnesia from the precursor bodies allows this proper wetting intergranular film to form and be maintained resulting in a single growing abnormal grain instead of producing multiple abnormal grains as in some known processes.

According to principles of the present invention, the vaporization rate of magnesia is controlled in a preferred embodiment of a single crystal conversion process via manipulation of the sintering process temperature and atmosphere. In a preferred embodiment, the sintering atmosphere contains a gas mixture including a predetermined partial pressure or concentration of hydrogen mixed with an inert gas. In a preferred embodiment, the inert gas used may be nitrogen (N₂). Hydrogen vaporizes magnesia preferentially from alumina at high temperatures. As further described herein, selection of an amount of hydrogen for the sintering atmosphere with a corresponding ideal sintering temperature maintains a wetting type intergranular film and reduces the likelihood of multiple abnormal grain formation in a polycrystalline body.

Although the use of hydrogen-nitrogen-containing sintering atmospheres has been reported for making translucent polycrystalline alumina components, as described in U.S. Pat. No. 7,247,591 to Wei which is incorporated herein by reference in its entirety, the conventional wisdom heretofore was that such an atmosphere could not be used in a single crystal conversion process to reliably produce single crystals or sapphires. It is worth noting that the use of the mixed gas in the Wei patent for densifying a polycrystalline final component was to reduce the cost of handling pure hydrogen, which is explosive, by switching to a non-flammable mixture (approximately less than 5% hydrogen). The polycrystalline tubes sintered in these gases commercially are also sintered with an MgO-charge powder and are sintered under conditions where abnormal grain growth does not occur.

The inventors have discovered a unique relationship between sintering process temperatures and partial pressures of hydrogen in a nitrogen sintering atmosphere that is necessary for the nucleation of single crystals in magnesia-doped alumina polycrystalline bodies. These ideal hydrogen content-temperature combinations produce the wetting-type intergranular film necessary for single crystal nucleation within relatively narrow processing windows. Deviation in the single crystal conversion process either above or below these optimized or ideal hydrogen content-temperature process windows will result in the formation of multiple abnormal grains instead of the desired single crystal. This fact, and prior general lack of understanding of the mechanism for single crystal conversion (i.e. formation of a wetting intergranular film) and the necessity to precisely control the vaporization rate of magnesia caused prior attempts at single crystal conversion to have lower conversion efficiencies. This lead to the misconception that hydrogen-nitrogen mixture sintering atmospheres were not suited for single crystal conversion of polycrystalline alumina. In one exemplary embodiment of a preferred solid state single crystal conversion process, a method for producing a transparent single crystal alumina components begins with providing a pre-fired densified polycrystalline alumina precursor component. The component may be of any type structure and configuration depending on its intended application including tubes such as those used in high pressure sodium vapor arc discharge lamps, cylinders/rods, cubes, sheets, etc. Accordingly, any suitable shaped component may be used and the invention is not limited to any particular shape. Preferably, the polycrystalline alumina component has been prepared and doped with magnesia as a sintering aid before the initial alumina densification-polycrystalline formation process by any conventional method commonly used in the art. In some embodiments, the magnesia-doped polycrystalline alumina precursor component may be prepared from commercial high purity alumina oxide powders mixed with magnesia that are then consolidated by conventional methods well known in the art, which may include injection molding, isopressing, casting, extrusion, and others. The method used will in part depend on the configuration of the precursor component, such as for example isopressing and extrusion for tubular shapes, and injection molding and casting for more complex shapes. In a preferred embodiment, the polycrystalline component is doped with about 500 ppm magnesia which is common for polycrystalline densification processes; however other suitable amounts of magnesia may be used to densify the polycrystalline alumina body in the precursor formation sintering process. In some embodiments, at least about 100 to 1000 ppm of magnesia may be used.

The preferred single crystal conversion process continues by placing the polycrystalline alumina component in a commercial sintering furnace or other heating apparatus that is structured for providing an enclosure suitable for establishing a controlled sintering atmosphere. In one embodiment, a refractory metal furnace such as those available from for example Centorr Vacuum Industries™ of Nashua, N.Y. may be used. In other embodiments, a heating apparatus with enclosure adapted for high temperature sintering by microwave energy in a controlled atmosphere may be used. The invention is therefore not limited to use of any particular type of heating/confinement apparatus, or energy source, for performing the high temperature sintering.

In a preferred embodiment, the sintering atmosphere preferably is a gas mixture comprised of hydrogen and nitrogen. The sintering atmosphere preferably includes less than about 20% hydrogen in nitrogen in some exemplary embodiments, and more preferably about equal to or less than about 10% hydrogen in other exemplary embodiments. Preferably, the concentration of hydrogen is less than 100%.

The preferred single crystal conversion process next continues by heating the polycrystalline alumina component to a relatively high temperature less than about 2050° C., which is the melting point of alumina (i.e. “sintering”). In some exemplary embodiments, the sintering temperature is preferably above about 1600° C. and less than 2050° C. In some embodiments, the sintering temperature is preferably greater than or equal to about 1800° C. As will be described elsewhere herein, any suitable sintering temperature may be used so long as the corresponding ideal hydrogen concentration is selected for the sintering atmosphere for forming a wetting-type intergranular film and single crystal.

The polycrystalline alumina component is held at the selected sintering temperature for a period of time sufficient to nucleate a single abnormal grain and to grow the single grain so that it consumes all polycrystalline grains to form a component having a single crystal structure. In some embodiments, the single abnormal grain may be nucleated or initiated in about one hour. The length of the sintering time necessary to complete the single crystal conversion process and produce a transparent alumina ceramic component will vary depending on the configuration and size of the polycrystalline alumina precursor component. In some embodiments of the single crystal conversion process, the use of chemical starters to induce formation of a single abnormal grain may be used. The starter may be any suitable chemical additive commonly used in a single crystal conversion process for alumina, such as without limitation silicon, calcium, titanium, and others. In some embodiments, the chemical additive may be added to the alumina starter powder when any sintering aids such as magnesia may be added, all prior to heating and densification of the polycrystalline component.

### EXAMPLES

A range of ideal hydrogen content-temperature combinations for sintering were identified and validated through testing by the inventors to guide those skilled in the art in conducting the single crystal conversion process described herein. In one particular non-limiting example of a preferred single crystal conversion process, the precursor or starting components were pre-fired alumina polycrystalline tubes doped with 500 ppm magnesia. The tubes were prepared by conventional methods from commercially-available finely divided alumina oxide powder with magnesia added as a sintering aid. These precursor tubes had an inner diameter of 1.25 mm, outer diameter of 3.30 mm, and a length of 30 mm. In one non-limiting example, the tubes were sintered in a refractory metal furnace for 4 hours at a temperature of 1945° C. and varying concentrations of hydrogen mixed with nitrogen in the atmosphere (i.e. N₂—X % H₂, where X=content or amount of H₂). The samples were heated/cooled at a rate of 16.5° C. per minute. The processes sample tubes were then analyzed using a variety of conventional techniques including optical microscopy, TEM (transmission electron microscopy), STEM (scanning transmission electron microscopy), EBSD (electron back-scatter diffraction), and EDS energy-dispersive spectroscopy).

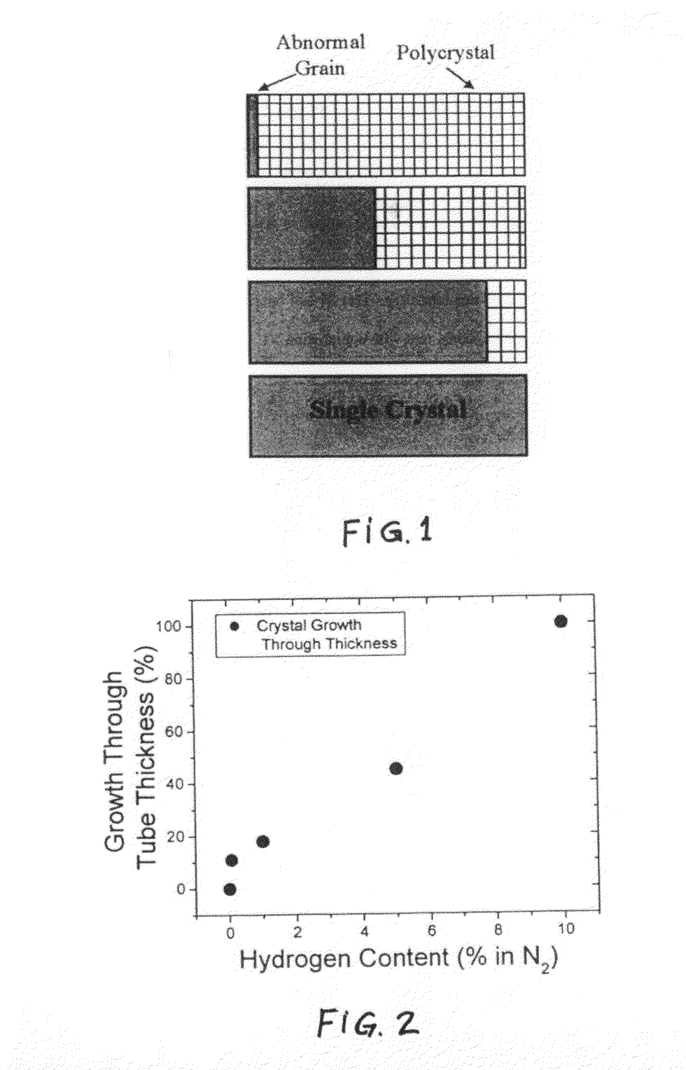

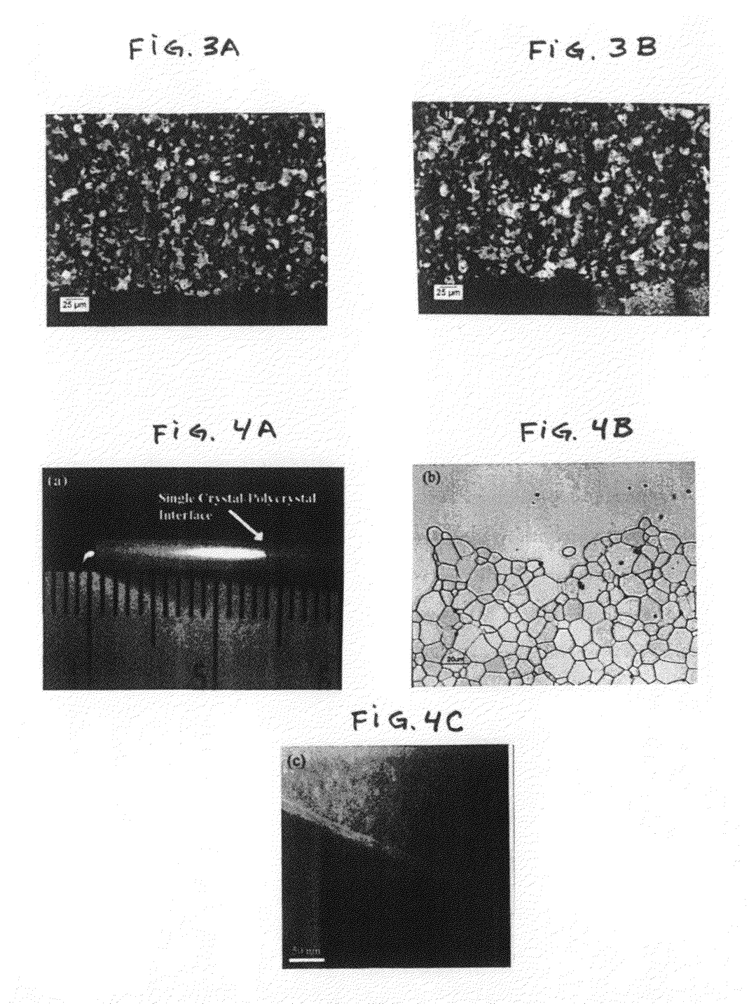

FIG. 2 shows the results of the foregoing single crystal conversion tests conducted at a selected sintering temperature of 1945° C. for 4 hours and varying concentrations of hydrogen. Grains were observed to have grown to 100% of the tube wall thickness for all hydrogen compositions shown greater than 0.07% in the hydrogen-nitrogen sintering atmosphere. However, there was not necessarily single grain growth at all concentrations of hydrogen indicated in FIG. 2. The results revealed that multiple abnormal grains had formed at some concentrations of hydrogen. However, a single abnormal grain was observed at a hydrogen content of 5%. Accordingly, the results illustrate that a hydrogen content of 5% requires an ideal corresponding sintering temperature of 1945° C. for the nucleation of only a single abnormal grain necessary to produce a single crystal. The single abnormal grain formed at 1945° C. and 5% hydrogen is visible in the optical micrograph of tube shown in FIG. 3A. The single abnormal grain is visible growing through the thickness of and along the length of the tube (visible at bottom of micrograph). Desired abnormal single grains were observed to grow at a rate of at least 2 cm/hour, and in excess of 8 cm/hour were achievable at upper bounds of the test. A processing window of ±10° C. at any particular ideal hydrogen content-temperature combination is believed to be applicable without adversely affecting the single crystal conversion. When ideal conditions were discovered for any particular hydrogen content the temperatures above and below this ideal temperature were probed. In each case, the ideal ‘window’ was approximately 10° C. Accordingly, a sintering temperature range of about 1935° C. to about 1955° C. (with 1945° C. being ideal) would nucleate a single abnormal grain at a hydrogen concentration of 5% in the sintering atmosphere. Single crystals of up to 4 cm were grown, which were limited by the size of the furnace hot zone. Accordingly, larger furnaces may be used to produce larger single crystal components.

At hydrogen concentrations above or below the ideal combination of 5% hydrogen and a sintering temperature of 1945° C., multiple abnormal grains instead were observed growing through the thickness of and along the length of the tubes as exemplified by the optical micrograph shown in FIG. 3B. The multiple abnormal grains are visible across bottom of micrograph).

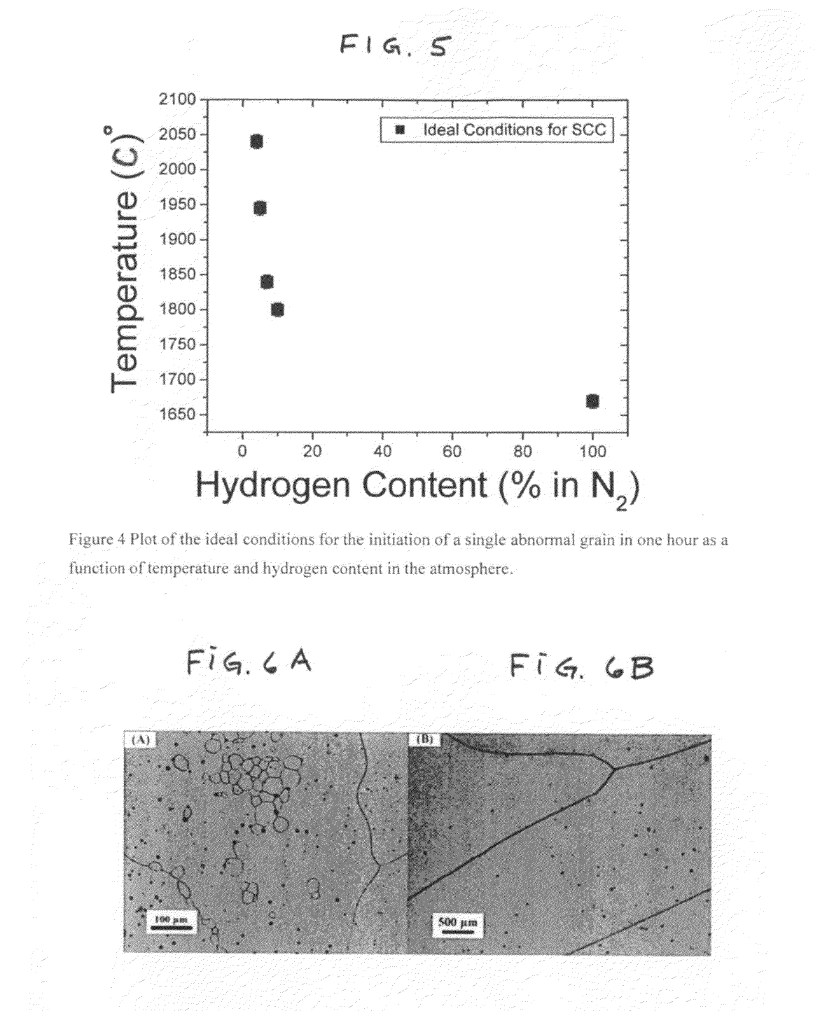

From the foregoing test, FIG. 4A is a photograph of a magnesia-doped polycrystalline alumina tube sample that was interrupted during the single crystal formation process using the controlled sintering atmosphere as described herein at the predetermined ideal hydrogen content-temperature combination. The sample tube was quenched at the end of its anneal in preparation for further analysis by TEM. The single crystal-polycrystal interface is visible in FIG. 4A. In FIG. 4B, an optical micrograph of the single crystal-polycrystal grain boundary from FIG. 4A is visible. FIG. 4C is a diffuse dark-field TEM image of that same crystal-polycrystal grain boundary wherein a wetting-type intergranular film associated with single crystal formation in alumina ceramics is seen. The wetting type film was found to have a thickness of about 10 nm to about 20 nm, which produces the most highly mobile grain boundaries in alumina and necessary for achieving reproducible single crystal conversion. Film thickness was observed to vary slightly between different individual boundaries.

The foregoing test results illustrate that single crystals can be reliably formed in polycrystalline alumina precursor bodies by prudent selection of sintering temperatures and associated partial pressures of hydrogen in the sintering atmosphere. At temperatures below any particular ideal hydrogen content-temperature range combination, unwanted multiple abnormal grains will grow at relatively slower grain boundary transport rates than at the ideal conditions. In general, grain boundary transport rates or velocity increase with a corresponding increase in process temperature (the velocity being directly proportional to the driving force of the migration and boundary mobility which is affected by temperature). Hence, the time necessary to complete the single crystal conversion process relates to grain boundary transport rate. At temperatures above any particular ideal hydrogen content-temperature range combination, multiple abnormal grains will grow albeit at faster grain boundary transport rates than the ideal conditions. However, at any particular ideal hydrogen content-temperature range combination, a single abnormal grain will grow for producing a single crystal alumina structure at an optimum grain boundary transport rate which reduces the conversion process time yielding associated economies. In part, the formation of multiple abnormal grains is attributable to the fact that if the magnesia evaporates too quickly, a single crystal will grow on the surface of the polycrystalline precursor object (e.g. tube, etc.) blocking the further vaporization and diffusion of magnesia which is now trapped inside the precursor. The trapped magnesia will prevent formation of the single crystal inside the precursor object leaving behind a polycrystalline structure embedded therein and only partial single crystal formation in the object. At hydrogen content-temperature combinations below the ideal range, the wetting-type intergranular film will not form, instead, other competing and undesirable grain boundary structures will form.

Using the foregoing test methodology, the single crystal conversion process was repeated at various hydrogen concentrations and temperatures to determine the ideal hydrogen content-temperature combinations that may be used in the process at several different predetermined temperatures based on the percentage hydrogen preselected for the sintering atmosphere. The same methodology and magnesia-doped polycrystalline alumina precursor components as described in the test above were used. Hydrogen concentrations (in nitrogen) were varied from 100% pure hydrogen to 0.01%. The results are shown in FIG. 5.

Referring now to FIG. 5, a range of ideal hydrogen content-temperature combinations that may be used with the preferred single crystal conversion process described herein are shown. FIGS. 5 is a plot of sintering temperatures versus percent hydrogen in a nitrogen sintering atmosphere. The same polycrystalline tubes described above and with 500 ppm magnesia dopant were sintered in N2—0.01% H2 at 2035° C., N2—5% H2 at 1945° C., N2—7% Hz at 1840° C., N2—10% H2 at 1800° C., and pure H2 at 1670 for 0-2 hours. These parameters represent the ideal hydrogen content-temperature combinations that may be used to produce single crystal alumina components in a solid state conversion process. Single abnormal grains associated with producing a single crystal resulted. The foregoing ideal temperatures from FIG. 5 may be varied about ±10° C. and still produce a single crystal. Grain boundary mobilities measured were 5.00×10⁻¹⁰ m³N⁻¹s⁻¹ at 1945° C., 4.04×10⁻¹⁰ m³N⁻¹s⁻¹ at 1840° C., 5.5×10⁻¹¹ m³N⁻¹s⁻¹ at 1945° C., and 1.20×10⁻¹¹ m³N⁻¹s⁻¹ at 1670° C. These mobilities (times the boundary pressure which drives the movement) are directly proportional to grain boundary transport rates. Accordingly, grain boundary mobility directly correlates to rate at which the single abnormal grain grows and hence the time required to complete the single crystal conversion process.

In general, higher process temperatures are associated with higher grain boundary mobilities and higher single crystal conversion speeds. However, higher process temperatures generally consume more energy with associated higher costs. Hydrogen content less than 5% are generally not flammable and therefore do not require the same safety precautions as higher concentrations of hydrogen. Accordingly, one skilled in the art can select an appropriate ideal hydrogen content-temperature combination for a particular application by balancing the foregoing considerations.

Those skilled in the art will be able to follow the foregoing methodology to readily determine and predict other ideal hydrogen content-temperature combinations. The single crystal conversion process may be interrupted and test samples quenched as described herein to analyze the samples for the nucleation of a single abnormal grain and formation of the proper wetting-type intergranular film necessary for single crystal formation.

The preferred single crystal conversion process for polycrystalline alumina described herein and demonstrated via the foregoing non-limiting examples was found to have reproducibility rates of about 80% in contrast to 30-40% associated with prior known conversion processes. This is the level of reliable necessary for commercial scale production of single crystal alumina ceramic components. These results are based on measurements from approximately 20 consecutively and individually sintered samples processed under the same conditions.

FIGS. 6A and 6B are optical micrographs of samples sintered below and above the ideal hydrogen content-temperature combination, respectively. As discussed above, multiple abnormal grains can be observed instead of the desired single abnormal grain necessary for forming a single crystal.

In some known single crystal conversion techniques such as described in U.S. Pat. Nos. 5,683,949, 5,451,553, and 6,475,942, initial magnesia concentrations must first lowered by an extra processing step of first separately heating the densified polycrystalline precursor material in a pure dry hydrogen atmosphere before the actual conversion process even begins. By contrast, the single crystal conversion method process of the present invention advantageously eliminates such separate magnesia-reduction steps through the use of a partial pressure hydrogen sintering atmosphere and corresponding sintering temperatures to control the evaporation rate of magnesia in a manner which does not adversely affect nucleation of a single abnormal grain. Accordingly, process times and costs may be reduced by elimination of the separate magnesia-lowering step.

The optimized single crystal conversion process described herein using a sintering atmosphere of hydrogen and nitrogen has improved conversion speeds associated with high grain boundary transport rates, higher reproducibility than presently obtainable with known conversion processes, and associated economies necessary for commercially-viable production of single crystal structures.

While the foregoing description and drawings represent the preferred embodiments of the present invention, it will be understood that various additions, modifications and substitutions may be made therein without departing from the spirit and scope of the present invention as defined in the accompanying claims. In particular, it will be clear to those skilled in the art that the present invention may be embodied in other specific forms, structures, arrangements, proportions, sizes, and with other elements, materials, and components, without departing from the spirit or essential characteristics thereof. One skilled in the art will appreciate that the invention may be used with many modifications of structure, arrangement, proportions, sizes, materials, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims, and not limited to the foregoing description or embodiments.

What is claimed is:

1. A solid state method for converting a polycrystalline alumina component into a single crystal component comprising:
providing a pre-fired polycrystalline alumina component;
heating the component to a predetermined temperature in a sintering atmosphere containing a gas mixture of nitrogen and a selected percentage of hydrogen; and
holding the component at said temperature for a time sufficient to convert the polycrystalline component into a single crystal component.

2. The method of claim 1, wherein the polycrystalline component contains an amount of magnesia.

3. The method of claim 1, wherein the heating step includes forming a wetting-type intergranular film in the grain boundary between the single crystal and unconverted polycrystalline alumina in the component.

4. The method of claim 1, wherein the temperature is between at least 1600° C. and less than 2050° C.

5. The method of claim 1, wherein the predetermined temperature is dependent on the percentage of hydrogen selected.

6. The method of claim 1, wherein the temperature in the heating step is between at least 1600° C. and 2050° C. and the amount of hydrogen in the sintering atmosphere is from at least 4% to 10% of the atmosphere.

7. The method of claim 2, wherein the amount of magnesia is about 500 ppm.

8. The method of claim 1, wherein the component is a tube.

9. The method of claim 1, wherein a chemical additive for inducing abnormal grain growth has been added to the polycrystalline component.

10. A solid state method for converting a polycrystalline alumina component into a single crystal component comprising:
providing a pre-fired polycrystalline alumina component doped with an amount of magnesia;
heating the component to a predetermined sintering temperature in a mixed sintering atmosphere consisting essentially of nitrogen and a selected percentage of hydrogen;
forming a wetting-type intergranular film; and
holding the component at the sintering temperature for a time sufficient to convert the polycrystalline component into a single crystal component.

11. The method of claim 10, wherein the amount of magnesia is about 500 ppm.

12. The method of claim 11, wherein the temperature is between at least 1600° C. and less than 2050° C.

13. The method of claim 10, wherein the amount of hydrogen is less than about 20%.

14. The method of claim 10, wherein a single abnormal grain is grown in the heating step which grows at rate of at least 2 cm/hour.

15. The method of claim 10, wherein the intergranular film has a thickness from 10 nm to 20 nm.

16. A solid state method for preparing an alumina single crystal component from polycrystalline alumina comprising:
providing a pre-fired polycrystalline alumina component doped with an amount of magnesia;
placing the component in a mixed sintering atmosphere containing nitrogen and a percentage of hydrogen;
heating the component to a predetermined temperature between 1600° C. and less than 2050° C.;
nucleating a single abnormal grain;
forming a wetting-type intergranular boundary film; and
expanding the single abnormal grain so that the polycrystalline component is converted entirely into a single crystal component.

17. The method of claim 16, wherein the predetermined temperature is selected based on a selected percentage of hydrogen present in the sintering atmosphere.

18. The method of claim 16, wherein the amount of magnesia is about 500 ppm.

19. The method of claim 16, wherein the amount of hydrogen in the sintering atmosphere is from 4% to 10%.

20. The method of claim 16, wherein the component is a tube.
